(19) United States
(12) Patent Application Publication
(10) Pub. No.: US 2018/0128860 A1
(43) Pub. Date: May 10, 2018

(54) ELECTRONIC COMPONENT

(71) Applicant: AISIN SEIKI KABUSHIKI KAISHA, Kariya-shi (JP)

(72) Inventors: Hiromu KINOSHITA, Nagoya-shi (JP); Noriaki FUJITA, Chita-gun (JP)

(73) Assignee: AISIN SEIKI KABUSHIKI KAISHA, Kariya-shi (JP)

(21) Appl. No.: 15/795,375

(22) Filed: Oct. 27, 2017

(30) Foreign Application Priority Data
Nov. 4, 2016 (JP) 2016-216373

(51) Int. Cl. G01R 15/20; G01R 19/00

(52) U.S. Cl. CPC G01R 15/202; G01R 19/0092

(57) ABSTRACT

An electronic component includes a first package in which an element is contained, a second package being provided apart from the first package, a lead being electrically connected to the element within the first package, extending from the first package, and penetrating the second package, and an electrode portion being formed such that a distal end side of the lead is bent relative to an extending direction of the lead from the first package to the second package.

### CROSS REFERENCE TO RELATED APPLICATIONS

This application is based on and claims priority under 35 U.S.C. §119 to Japanese Patent Application 2016-216373, filed on Nov. 4, 2016, the entire content of which is incorporated herein by reference.

### TECHNICAL FIELD

This disclosure generally relates to an electronic component.

### BACKGROUND DISCUSSION

An electronic component with a lead (hereinafter referred to as a lead component) being provided such that the lead extends from a mold portion, the electronic component serving as an electronic component mounted to a substrate (for example, a plastic substrate), has been used. This kind of lead component may include the mold portion at a distal end portion of the lead in order to be prevented from bending when, for example, being transported within a factory in a case of being delivered from a manufacturer. This kind of lead component is mounted to the substrate by cutting the lead immediately before the mounting, by cutting off the mold portion of the distal end portion, and by being mounted on and welded to the substrate by a laser soldering process after being formed in a desired form. To enhance the productivity in the mounting process of the lead component to the substrate, devices performing a lead forming process and a laser soldering are required to be additionally provided, and therefore, cost may be increased. Here, the lead forming process may be discontinued by the change of the lead component to a surface mounting component, and the component may be solder-welded by using a reflow furnace (for example, in JP2016-109601A (hereinafter referred to as Patent reference 1).

According to a current sensor disclosed in Patent reference 1, a circumference of a conductor (bus bar) in which a current flows is surrounded by a core including a gap at a part thereof in a circumferential direction, and a magnetic flux density of a flux generated at the gap is measured by a hall element (a magnetic detection element), and the current is detected based on the measured result.

In the technology disclosed in Patent reference 1, on a principle of a hall element, a substrate has to be provided with the hall element at the gap of the core. Accordingly, because the gap is required to be enlarged, the size of the core increases, and therefore, the detection precision may be decreased. Instead of the technology disclosed in Patent reference 1, a surface-mounting-type package (for example, a package that may be mounted in a state where the mold portion is standingly provided relative to the substrate) in which the only mold portion with the hall element contained may be disposed at the gap may be developed. However, this kind of package may correspond to a custom package requiring a large amount of development costs, and therefore, the cost may be increased.

A need thus exists for an electronic component which is not susceptible to the drawback mentioned above.

### SUMMARY

According to an aspect of this disclosure, an electronic component includes a first package in which an element is contained, a second package being provided apart from the first package, a lead being electrically connected to the element within the first package, extending from the first package, and penetrating the second package, and an electrode portion being formed such that a distal end side of the lead is bent relative to an extending direction of the lead from the first package to the second package.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is a perspective view of an electronic component of a first embodiment disclosed here;

FIG. 2 is a view illustrating a state where the electronic component is mounted to a substrate;

FIG. 3 is a view illustrating an electronic component of a second embodiment; and

FIG. 4 is a view illustrating an electronic component of a third embodiment.

### DETAILED DESCRIPTION

A first embodiment will hereunder be explained with reference to the drawings. An electronic component of the first embodiment may be implemented with a low cost in a state of being standingly provided relative to a substrate. Hereinafter, an electronic component 1 of the first embodiment will be explained, and a hall IC may be an example of the electronic component 1.

The hall IC detects a measured current flowing in a conductor 2. Here, in a case where the current flows in the conductor 2, a magnetic field making the conductor 2 be a center axis is generated in response to the volume of the current, and a magnetic flux is generated by the magnetic field. The hall element that is contained by the hall IC detects the density of the magnetic flux, and the hall IC detects current (a current value) flowing in the conductor 2 based on the magnetic flux density detected by the hall element.

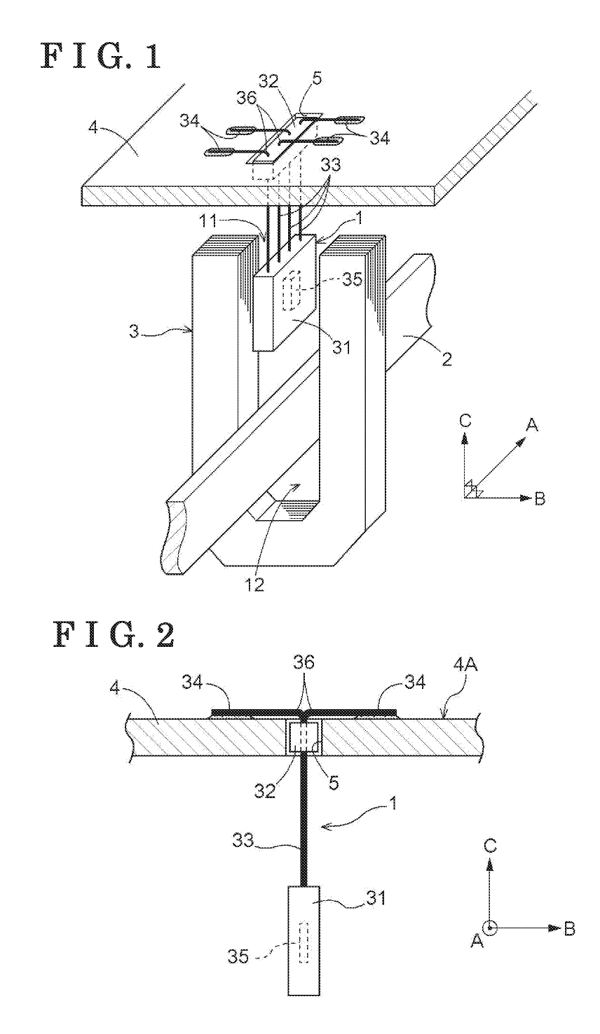

For an easy understanding, in FIG. 1, an extending direction of the conductor 2 in which the measured current flows corresponds to a direction A, and directions perpendicular to the direction A correspond to a direction B and a direction C.

Here, the conductor 2 is provided in a groove portion 12 of a substantially U-shaped core 3. In the first embodiment, the conductor 2 corresponds to a bus bar electrically connecting a three-phase rotary electronic device and an inverter controlling a rotation of the three-phase rotary electronic device. Three of the bus bars are provided in the three-phase rotary electronic device. In this case, the electronic component 1 is provided at each of the three conductors 2. Only one bus bar is illustrated in FIG. 1.

The substantially U-shaped core 3 includes an opening part 11 at a part thereof and is made from a magnetic body including the groove portion 12. The conductor 2 is provided in the groove portion 12 of the core 3. Accordingly, the magnetic flux generated at a circumference of the conductor 2 may be easily collected at the core 3.

The electronic component 1 is provided at the opening part 11 of the groove portion 12. The electronic component 1 includes a first package 31, a second package 32, leads 33, and electrode portions 34.

An element 35 is contained in the first package 31. The element 35 in the first embodiment corresponds to a hall element detecting the magnetic flux density of the magnetic flux generated at the circumference of the conductor 2 in response to the current flowing in the conductor 2. The hall element detects the magnetic flux density of the magnetic flux generated at the opening part 11 of the groove portion 12. The first package 31 is molded by using resin in a state of containing such a hall element. The first package 31 is disposed such that a detecting surface of the hall element is arranged perpendicular to the magnetic flux generated at the opening part 11 of the groove portion 12.

The second package 32 is disposed apart from the first package 31. As described above, in the first embodiment, the first package 31 is disposed at the opening part 11 of the core 3. The second package 32 is separately molded from the first package 31 by using resin, and is disposed outward relative to the groove portion 12 of the core 3.

The lead 33 is electrically connected to the element 35 within the first package 31. The element 35 (the hall element in the first embodiment) is contained in the first package 31. The lead 33 is made from a conductor, and is molded by using resin in a state of being electrically connected to a terminal of the element 35. In the first embodiment, the hall element includes a power supply terminal, a reference voltage terminal, and an output terminal. In an example in FIG. 1, three of the leads 33 are electrically connected to the power supply terminal, the reference voltage terminal, and the output terminal, respectively, and the remaining one of the leads 33 is connected to an unconnected terminal (a so-called non-connected terminal, or a NC terminal) that does not electrically connect with the power supply terminal, the reference voltage terminal, and the output terminal. The four leads 33 are molded with the element 35 by using resin.

The lead 33 extends from the first package 31 and is provided in the second package 32. The lead 33 is electrically connected to the element 35 within the first package 31. The aforementioned second package 32 is molded by using resin such that the lead 33 is provided therein.

In the first embodiment, the lead 33 penetrates the second package 32 via two surfaces of the second package 32 facing with each other. The second package 32 is formed in a rectangular-parallelepiped shape as shown in FIG. 1. The lead 33 is provided so as to penetrate the second package 32 from a predetermined surface of the surfaces (that is, six surfaces) of the rectangular-parallelepiped-shaped second package 32 through a surface facing the predetermined surface.

The electrode portions 34 are each formed such that a distal end side of the lead 33 is bent relative to an extending direction of the lead 33 from the first package 31 to the second package 32. The extending direction of the lead 33 from the first package 31 to the second package 32 corresponds to a direction with which the lead 33 provided between the first package 31 and the second package 32 faces. Here, in the first embodiment, the lead 33 is formed in a straight line shape between the first package 31 and the second package 32. In the example in FIG. 1, C direction corresponds to the extending direction of the lead 33.

The distal end side of the lead 33 is a side (serving as a base side) opposite to a side where the first package 31 is provided, and corresponds to a free-end side of the lead 33. Bending of the distal end side of the lead 33 relative to the extending direction corresponds to the bending of the free-end side of the lead 33 so as to include a predetermined angle relative to the direction with which the lead between the first package 31 and the second package 32 faces. In the first embodiment, a bending portion 36 corresponding to a center of the bent part of the lead 33 is provided at a distal end side of the lead 33 relative to the second package 32, that is, at a side of the lead 33 protruding relative to the second package 32.

In the first embodiment, the electrode portion 34 corresponds to a distal end side of the lead 33 relative to the bending portion 36. The electronic component 1 may be mounted to the substrate 4 via the electrode portion 34. FIG. 2 illustrates a side surface view in a state where the electronic component 1 is mounted to the substrate 4. The second package 32 is inserted into the through hole 5 provided at the substrate 4 from the side where the first package 31 of the electronic component 1 is provided. Here, the electrode portion 34 is in contact with a surface 4A of the substrate 4 (for example via a solder cream), and the second package 32 is provided in the through hole 5. Accordingly, the electronic component 1 may be positioned on the substrate 4. In such a state, the electrode portion 34 and a land provided at the surface 4A of the substrate 4 are welded with each other by using, for example, the solder by a reflow soldering (reflow process). By adjusting the length of the lead 33 between the first package 31 and the second package 32, the positioning relationship from the substrate 4 to the element 35 may be freely set.

As such, the electronic component 1 may be implemented by the reflow soldering in a state where the first package 31 in which the element 35 is contained is standingly provided relative to the substrate 4. Thus, even in a case where a hall element is used as the element 35, the magnetic flux may be inputted in a direction perpendicular to, or orthogonal to the detecting surface of the hall element. In addition, because a conventional package may be used, the mass production is achieved without increasing the manufacturing cost, and the development cost for new packages is not required. Moreover, by adjusting the interval between the first package 31 and the second package 32 (the length of the lead 33 between the first package 31 and the second package 32), the electronic component 1 may be adapted in products in which the lengths between the substrate 4 and the element 35 are different.

Further, by being bent immediately before the implementation, the lead 33 may be prevented from being bent when the electronic component 1 is delivered. Because a width dimension of the electronic component 1 on the delivery may be smaller than a width dimension of the first package 31, the electronic component 1 on the delivery may be downsized. Accordingly, a large amount of the electronic component 1 may be delivered at once, and therefore, the cost for delivery may be reduced.

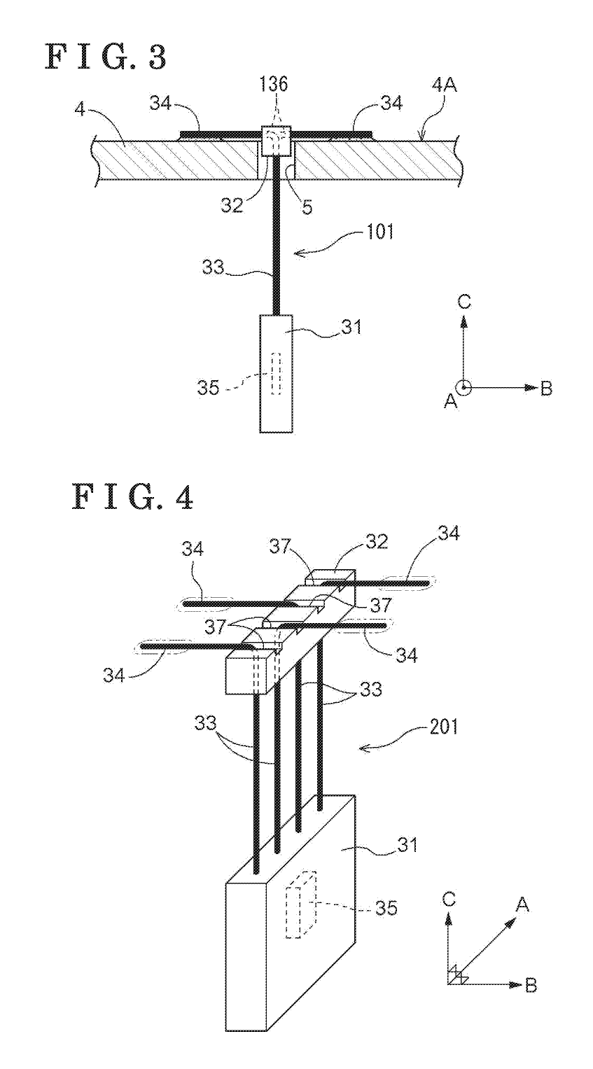

A second embodiment will hereunder be explained. In the aforementioned first embodiment, as shown in FIG. 2, the lead 33 penetrates the second package 32 via the two surfaces of the second package 32 facing with each other. Alternatively, as illustrated in FIG. 3, the lead 33 may penetrate the second package 32 via two surfaces of the second package 32 disposed adjacent to each other in a state where the lead is bent within the second package 32. Specifically, the lead 33 penetrates the second package 32 from a predetermined surface of the surfaces (that is, six surfaces) of the rectangular-parallelepiped-shaped second package 32 through a surface adjacent to the predetermined surface.

In this configuration, a bending portion 136 is contained in the second package 32, and the electrode portion 34 protrudes from the second package 32. An electronic component 101 may be mounted to the substrate 4 via the electrode portion 34. As illustrated in FIG. 3, the electronic component 101 is inserted into the through hole 5 provided at the substrate 4 from the side where the first package 31 is provided. Here, the electrode portion 34 is in contact with the surface 4A of the substrate 4, and the second package 32 is provided in the through hole 5. Accordingly, the electronic component 101 may be positioned relative to the substrate 4. In this state, the electrode portion 34 and a land provided at the surface 4A of the substrate 4 are welded with each other using, for example, the solder. The electronic component 101 of this configuration may be implemented in a state where the first package 31 in which the element 35 is contained is standingly provided relative to the substrate 4.

According to the aforementioned first and second embodiments, the electrode portion 34 is formed such that the distal end side of the lead 33 is bent relative to the extending direction of the lead 33 from the first package 31 to the second package 32. To easily bend the distal end side of the lead 33, it is favorable that guide portions 37 are provided at a surface of the second package 32 where the distal end side of the lead 33 protrudes, the guide portions 37 guiding the distal end side of the lead 33 in a preset bending direction. The second package 32 having the guide portions 37 is illustrated in FIG. 4.

As illustrated in FIG. 4, the lead 33 extends from the first package 31 and enters into the second package 32, and the distal end side of the lead 33 protrudes from the surface of the second package 32 facing the surface into which the lead 33 enters. The guide portion 37 that easily bends the lead 33 in a predetermined direction (corresponds to the aforementioned bending direction) is provided at the surface of the second package 32 from which the distal end side of the lead 33 protrudes. In an example in FIG. 4, the guide portion 37 is formed as a groove portion extending along the bending direction. By bending each of the leads 33 along the groove portion, the electrode portion 34 may be provided to match a position of a land provided at the substrate 4. Thus, an electronic component 201 may be easily mounted to the substrate 4, and therefore, the productivity may be enhanced.

In the aforementioned first, second and third embodiments, the hall IC is an example of the electronic component 1, 101, 201. Alternatively, the electronic component 1, 101, 201 may be other than the hall IC.

In the aforementioned first and second embodiments, the second package 32 is formed in the rectangular-parallelepiped shape. Alternatively, the second package 32 may be formed in a shape other than the rectangular-parallelepiped shape, for example, may include a trapezoidal-shaped lateral cross section.

The disclosure is applicable to an electronic component mounted in a substrate.

According to the aforementioned embodiments, the electronic component 1, 101, 201 includes the first package 31 in which the element 35 is contained, the second package 32 being provided apart from the first package 31, the lead 33 being electrically connected to the element 35 within the first package 31, extending from the first package 31, and penetrating the second package 32, and the electrode portion 34 being formed such that the distal end side of the lead 33 is bent relative to the extending direction of the lead 33 from the first package 31 to the second package 32.

According to the characteristics of the configuration, while using the manufacturing process of a conventional lead-type electronic component, the electronic component 1, 101, 201, which is implemented in a state where the first package 31 with the element 35 contained is standingly provided relative to the substrate 4, may be provided. Accordingly, for example, in a case where the hall element is applied as an element, the hall IC that can detect an applied magnetic flux in a direction parallel to the surface of the substrate 4 may be provided. Because a conventional lead-type package may be used, the development cost of the package is inhibited from increasing. In addition, because a conventional surface mounting equipment may be used to mount the electronic component 1, 101, 201 of this configuration to the substrate 4, the cost of equipment may be inhibited from increasing. According to the electronic component 1, 101, 201, a small electronic component with a lead may be implemented with low cost.

According to the aforementioned embodiments, the lead 33 penetrates the second package 32 via the two surfaces of the second package 32 facing with each other.

According to the aforementioned configuration, a dimension of the electronic component 1 in a thickness direction may be a dimension of the first package 31 and the second package 32 in the thickness direction until a distal end portion of the lead 33 is bent. Thus, the conventional equipment (for example, transportation equipment) may be used before a process bending the distal end of the lead 33 is performed. Accordingly, the cost of equipment may be inhibited from increasing.

According to the aforementioned embodiment, the lead 33 penetrates the second package 32 via the two surfaces of the second package 32 being disposed adjacent to each other in a state where the lead 33 is bent within the second package.

In this configuration, the first package 31 in which the element 35 is contained may be mounted to the substrate 4 by the surface mounting process in a state of being standingly provided relative to the substrate 4. Accordingly, because the conventional surface mounting equipment may be used, the cost of equipment may be inhibited from increasing.

According to the aforementioned embodiment, the second package 32 includes the guide portion 37 being provided on the surface from which the distal end side of the lead 33 protrudes, the guide portion 37 guiding the distal end side of the lead 33 in the preset bending direction.

For example, when mounting the electronic component 1 to the substrate 4, the lead 33 relative to the land may be inhibited from being mispositioned by including the guide portion 37 so as to bend the lead 33 toward the land provided at the substrate 4. Accordingly, in the configuration, the lead 33 may be easily bent in a desired direction, and the electronic component 1 may be easily attached to the land.

According to the aforementioned embodiment, the guide portion corresponds to a groove portion being formed in the bending direction.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

1. An electronic component, comprising:
a first package in which an element is contained;
a second package being provided apart from the first package;
a lead being electrically connected to the element within the first package, extending from the first package, and penetrating the second package; and
an electrode portion being formed such that a distal end side of the lead is bent relative to an extending direction of the lead from the first package to the second package.

2. The electronic component according to claim 1, wherein the lead penetrates the second package via two surfaces of the second package facing with each other.

3. The electronic component according to claim 1, wherein the lead penetrates the second package via two surfaces of the second package being disposed adjacent to each other in a state where the lead is bent within the second package.

4. The electronic component according to claim 1, wherein the second package includes a guide portion being provided on a surface from which the distal end side of the lead protrudes, the guide portion guiding the distal end side of the lead in a preset bending direction.

5. The electronic component according to claim 4, wherein the guide portion corresponds to a groove portion being formed in the bending direction.
